(19) United States
(12) Patent Application Publication
(10) Pub. No.: US 2016/0358751 A1
(43) Pub. Date: Dec. 8, 2016

(54) ARC DISCHARGE APPARATUS AND PLASMA PROCESSING SYSTEM INCLUDING THE SAME

(71) Applicants: Jong-hyun LEE, Bucheon-si (KR); Jung-woo SEO, Hwaseong-si (KR); Bo-kyung JUNG, Seoul (KR); Nam-hoon LEE, Ansan-si (KR); Gi-nam PARK, Incheon (KR); Sung-ho KANG, Hwaseong-si (KR); Tae-gon KIM, Seoul (KR); Jin-hwa HEO, Suwon-si (KR); Byung-joo OH, Seoul (KR); Gon-su KANG, Hwaseong-si (KR); Hyeok-jun KWON, Seoul (KR); Jin-seung LEE, Suwon-si (KR)

(72) Inventors: Jong-hyun LEE, Bucheon-si (KR); Jung-woo SEO, Hwaseong-si (KR); Bo-kyung JUNG, Seoul (KR); Nam-hoon LEE, Ansan-si (KR); Gi-nam PARK, Incheon (KR); Sung-ho KANG, Hwaseong-si (KR); Tae-gon KIM, Seoul (KR); Jin-hwa HEO, Suwon-si (KR); Byung-joo OH, Seoul (KR); Gon-su KANG, Hwaseong-si (KR); Hyeok-jun KWON, Seoul (KR); Jin-seung LEE, Suwon-si (KR)

(21) Appl. No.: 15/080,752

(22) Filed: Mar. 25, 2016

(30) Foreign Application Priority Data
Jun. 3, 2015 (KR) 10-2015-0078673
Sep. 24, 2015 (KR) 10-2015-0135555

(51) Int. Cl. H01J 37/32; C23C 16/455; C23C 16/458; C23C 16/50

(52) U.S. Cl. CPC H01J 37/32055; C23C 16/50; H01J 37/3244; C23C 16/45544; C23C 16/458; H01J 2237/334; H01J 2237/3321

(57) ABSTRACT

An arc discharge apparatus includes a body unit including a housing and a transmissive member fixed to the housing, the housing having a coolant inlet and a coolant outlet, and an electrode unit on the housing, the electrode unit including an anode and a cathode facing each other, wherein the anode includes a main body portion connected to the housing, an anode tip coupled to the main body portion, and a cooling line in the anode and in contact with an inner wall of the anode tip, the cooling line being connected to the coolant inlet and to the coolant outlet.

### CROSS-REFERENCE TO RELATED APPLICATION

Korean Patent Application Nos. 10-2015-0078673, filed on Jun. 3, 2015, and 10-2015-0135555, filed on Sep. 24, 2015, in the Korean Intellectual Property Office, and entitled: “Arc Discharge Apparatus and Plasma Processing System Including the Same,” are incorporated by reference herein in its entirety.

### BACKGROUND

1. Field

Example embodiments relate to an arc discharge apparatus and a plasma processing system including the same.

2. Description of the Related Art

As arc discharge apparatuses are used for applications requiring high power consumption, e.g., semiconductor manufacturing and solar simulation, thermal load applied to electrodes provided in the arc discharge apparatuses has increased. In particular, thermal load that is three times or more greater than that applied to cathodes may be applied to anodes to which electrons emitted from the cathodes enter. Accordingly, a research to extend the life of the anodes has been conducted in various ways.

### SUMMARY

Example embodiments provide an arc discharge apparatus including an electrode having an extended life.

Example embodiments also provide a plasma processing system including the arc discharge apparatus.

According to an aspect of the example embodiments, there is provided an arc discharge apparatus including a body unit having a housing and a transmissive member fixed to the housing, the housing having a coolant inlet and a coolant outlet, and an electrode unit on the housing, the electrode unit including an anode and a cathode facing each other, wherein the anode includes a main body portion connected to the housing, an anode tip coupled to the main body portion, and a cooling line in the anode and in contact with an inner wall of the anode tip, the cooling line being connected to the coolant inlet and to the coolant outlet.

The main body portion and the anode tip may include different materials.

The main body portion may include brass, copper, or a combination thereof.

The main body portion and the anode tip may be coupled to each other by using an adhesive member disposed on an adhesive surface between the main body portion and the anode tip.

A distance between the adhesive surface and a front end of the anode may be greater than a diameter of the anode tip.

The cooling line may include a first fluid passage extending from the coolant inlet to a portion adjacent to the anode tip and a second fluid passage extending from an outlet portion of the first fluid passage to the coolant outlet.

At least a part of the second fluid passage may be formed to surround an outer circumferential surface of the first fluid passage.

The first fluid passage may include: a first pipe extending from the coolant inlet; a third pipe spaced apart from the first pipe, extending toward the outlet portion of the first fluid passage, and having a cross-sectional area that is less than a cross-sectional area of the first pipe; and a second pipe disposed between the first pipe and the third pipe and having a cross-sectional area that decreases toward the third pipe.

A central portion of an inner upper wall of the anode may have a planar shape.

The anode tip may include a first tip disposed on a front end of the anode and a second tip disposed between the first tip and the main body portion, and the cooling line may include a first fluid passage extending from the coolant inlet to a portion adjacent to the second tip and a second fluid passage extending from an outlet portion of the first fluid passage to the coolant outlet, wherein a flow velocity of a coolant at the outlet portion of the first fluid passage is higher than a flow velocity of a coolant at the coolant inlet.

The first tip and the second tip may include different materials.

The first tip may include tungsten or a tungsten alloy and the second tip may include copper.

The first tip and the second tip may be coupled to each other by using an adhesive member disposed on an adhesive surface between the first tip and the second tip.

A plurality of the anodes may be formed.

Each of the plurality of anodes may include an induction coil wound around an outer circumferential surface of each of the plurality of anodes to generate an induced magnetic field, wherein the arc discharge apparatus includes a power control unit configured to selectively supply power to the induction coil of each of the plurality of anodes.

The power control unit may uniformly distribute power supplied to the induction coils of the plurality of anodes.

The plurality of anodes may be radially spaced apart from one another at same intervals.

The anode may include a coating unit formed to surround an outer circumferential surface of the anode.

The coating unit may include tungsten or a tungsten alloy.

According to another aspect of example embodiments, there is provided an arc discharge apparatus including: a body unit including a housing in which a coolant inlet and a coolant outlet are formed and a transmissive member fixed to the housing; and an electrode unit mounted on the housing and including an anode and a cathode disposed to face each other, wherein the anode includes a main body portion connected to the housing and an anode tip coupled to the main body portion, wherein the anode tip includes a first tip disposed on a front end of the anode and including tungsten or a tungsten alloy and a second tip disposed between the first tip and the main body portion, wherein a cooling line formed in the anode is connected to the coolant inlet and the coolant outlet and contacts an inner wall of the anode tip.

The first tip and the second tip may be integrally formed by using a same material.

The main body portion and the anode tip may be coupled to each other by using an adhesive member disposed on an adhesive surface between the main body portion and the anode tip, wherein a distance between the adhesive surface and the front end of the anode is greater than a diameter of the anode tip.

The second tip includes copper and the first tip and the second tip may be coupled to each other by using an adhesive member disposed on an adhesive surface between the first tip and the second tip, wherein the cooling line includes a first fluid passage extending from the coolant inlet to a portion adjacent to the second tip and a second fluid passage extending from an outlet portion of the first fluid passage to the coolant outlet, wherein a flow velocity of a coolant at the outlet portion of the first fluid passage is higher than a flow velocity of a coolant at the coolant inlet.

The anode may include a coating unit formed to surround an outer circumferential surface of the anode, and the coating unit includes tungsten or a tungsten alloy.

According to yet another aspect of the example embodiments, there is provided a plasma processing system including: a chamber configured to provide a space in which a plasma process is performed; a gas supply unit configured to supply a process gas into the chamber; a substrate support provided in the chamber and on which a substrate is mounted; and an arc discharge apparatus mounted on one surface of the chamber and configured to receive power and generate an arc discharge, wherein the arc discharge apparatus includes: a body unit including a housing in which a coolant inlet and a coolant outlet are formed and a transmissive member fixed to the housing; and an electrode unit mounted on the housing and including an anode and a cathode disposed to face each other, wherein the anode includes a main body portion and an anode tip coupled to the main body portion, and a cooling line formed in the anode contacts the anode tip.

The plasma processing system may include a cooling unit configured to supply a coolant to the cooling line.

The cooling line may include a first fluid passage extending from the coolant inlet to a portion adjacent to the anode tip and a second fluid passage extending from the first fluid passage to the coolant outlet, wherein a flow velocity of a coolant at the first fluid passage is higher than a flow velocity of a coolant at the coolant inlet.

The anode tip may include a first tip disposed on a front end of the anode and a second tip disposed between the first tip and the main body portion, wherein the first tip and the second tip include different materials.

According to yet another aspect of the example embodiments, there is provided an arc discharge apparatus, including a body unit including a housing having a coolant inlet and a coolant outlet, and an electrode unit in the housing, the electrode unit including an anode and a cathode facing each other, wherein the anode includes a main body portion connected to the housing, an anode tip coupled to the main body portion and facing the cathode, and a cooling line inside the anode and connected to the coolant inlet and outlet, at least a portion of the cooling line defines and extends along inner walls of the anode tip.

The cooling line includes may include a first fluid passage extending from the coolant inlet through the main body portion and into the anode tip, and a second fluid passage extending from an outlet portion of the first fluid along inner walls of the anode tip, the first and second fluid passages being concentric.

A cross-sectional area of the outlet portion of the first fluid passage may be smaller than a cross-sectional area of the coolant inlet portion.

The first fluid passage may include a first pipe extending from the coolant inlet, a third pipe spaced apart from the first pipe and extending toward the outlet portion of the first fluid passage, the third pipe having a cross-sectional area that is smaller than each of a cross-sectional area of the first pipe and the, and a second pipe connecting between the first pipe and the third pipe, the second pipe having a gradually decreasing cross-sectional area as a distance from the first pipe increases.

The main body portion and the anode tip may be coupled to each other via an adhesive member, a distance between the adhesive member and a front surface of the anode being greater than a width of the front surface of the anode, and the front surface of the anode facing the cathode.

The anode tip may be a uniform portion including a same material in its entirety between the front surface of the anode and the adhesive member.

### BRIEF DESCRIPTION OF THE DRAWINGS

Features will become apparent to those of ordinary skill in the art by describing in detail exemplary embodiments with reference to the attached drawings, in which:

FIG. 1 illustrates a side view of an arc discharge apparatus according to an exemplary embodiment;

FIG. 2 illustrates an enlarged, partial side view of an anode in an arc discharge apparatus according to an exemplary embodiment;

FIG. 3 illustrates a side cross-sectional view of FIG. 2;

FIG. 4 illustrates a top cross-sectional view taken along line A-A′ of FIG. 2;

FIG. 5 illustrates a cross-sectional view of a part of the anode according to an exemplary embodiment;

FIG. 6 illustrates a side view illustrating a part of an anode according to an exemplary embodiment;

FIG. 7 illustrates a cross-sectional view of a part of the anode;

FIG. 8 illustrates a side view of the anode according to an exemplary embodiment;

FIG. 9 illustrates a perspective view of an anode according to an exemplary embodiment;

FIG. 10 illustrates a plan view seen from a front end of the anode of FIG. 9;

FIGS. 11A and 11B illustrate diagrams of current supplied to an induction coil provided in the anode;

FIG. 12 illustrates a perspective view of the arc discharge apparatus according to an exemplary embodiment; and

FIG. 13 illustrates a cross-sectional view of a plasma processing system according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on”, “connected to,” or “coupled to” another layer, element, or substrate, it can be directly on, connected to, or coupled to another layer, element, or substrate, or intervening layers or elements may also be present. In addition, it will also be understood that when a layer or element is referred to as being “between” two layers or elements, it can be the only layer or element between the two layers or elements, or one or more intervening layers or elements may also be present. Like reference numerals refer to like elements throughout.

As used herein, the term “and/or” includes any and all combinations of one or more of the associated listed items. Expressions such as “at least one of” when preceding a list of elements, modify the entire list of elements and do not modify the individual elements of the list.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of exemplary embodiments.

Spatially relative terms, such as “above”, “upper”, “beneath”, “below”, “lower”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “above” other elements or features would then be oriented “below” the other elements or features. Thus, the exemplary term “above” may encompass both an orientation of above and below. The device may be otherwise oriented (rotated 90 degrees or at other orientations) and spatially relative descriptors used herein interpreted accordingly.

The terminology used herein is for the purpose of describing exemplary embodiments only and is not intended to be limiting of exemplary embodiments. As used herein, the singular forms “a”, “an”, and “the” are intended to include the plural forms as well, unless the context clearly indicates otherwise. It will be further understood that the terms “comprises” and/or “comprising” used herein specify the presence of stated features, integers, steps, operations, members, components, and/or groups thereof, but do not preclude the presence or addition of one or more other features, integers, steps, operations, members, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may include deviations in shapes that result, for example, from manufacturing. The following exemplary embodiments may be implemented individually or in combination.

An arc discharge apparatus and a plasma processing system described below may have various configurations, only necessary configurations are suggested herein, and the scope of the example embodiments is not limited thereto.

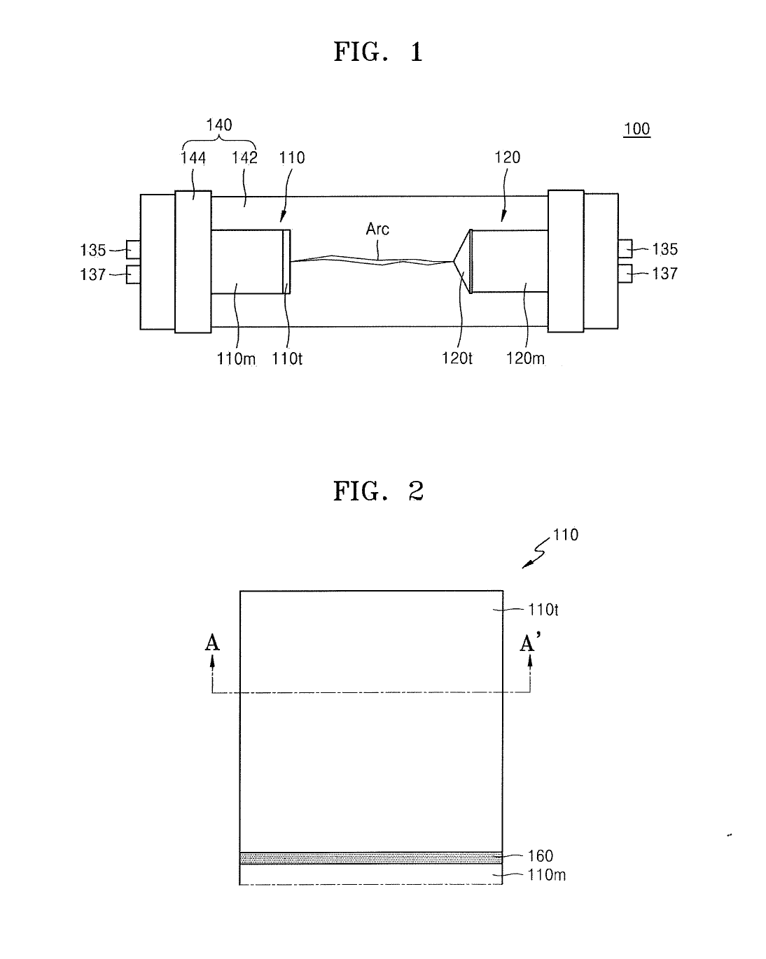

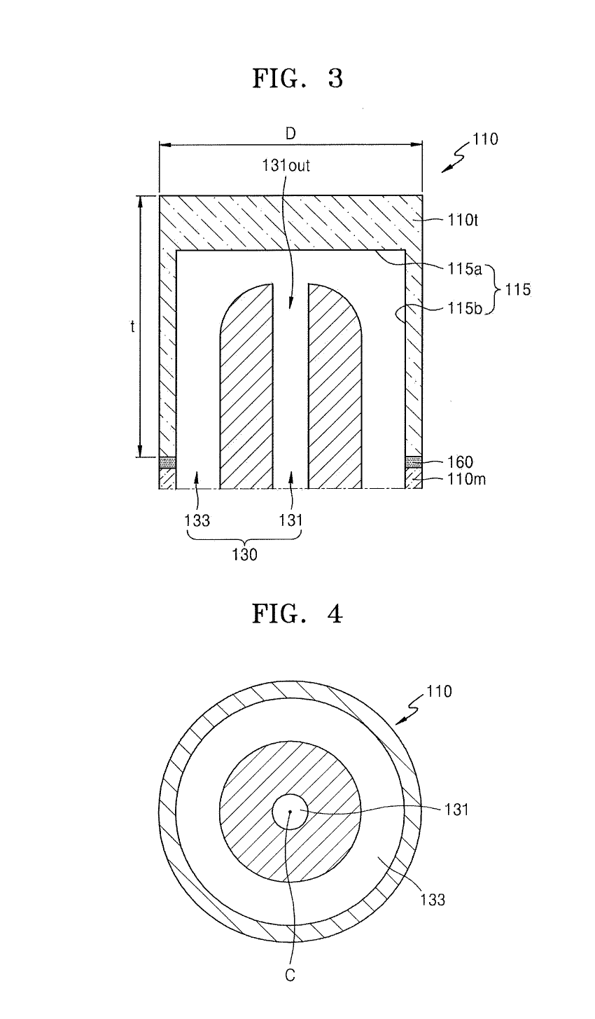

FIG. 1 is a side view of an arc discharge apparatus 100 according to an exemplary embodiment. FIG. 2 is an enlarged, partial side view of an anode 110 in the arc discharge apparatus 100, FIG. 3 is a side cross-sectional view of FIG. 2, and FIG. 4 is a top cross-sectional view taken along line A-A′ of FIG. 2.

Referring to FIG. 1, the arc discharge apparatus 100 may include a body unit 140 including a housing 144, in which a coolant inlet 135 and a coolant outlet 137 are formed, and a transmissive member 142 fixed to the housing 144, and an electrode unit mounted on the housing 144. The electrode unit may include the anode 110 and a cathode 120 disposed to face each other.

The body unit 140 may include the housing 144 and the transmissive member 142 fixed to the housing 144. The body unit 140 may be provided to have, e.g., a pipe shape.

A reactive gas may be contained in the body unit 140 and may be blocked from external air due to the body unit 140. The reactive gas contained in the body unit 140 may be discharged due to an arc formed between the cathode 120 and the anode 110, and a plasma generated in this process may emit radiant energy to the outside of the arc discharge apparatus 100. That is, the body unit 140 may provide a space in which the reactive gas may be discharged.

The anode 110 and the cathode 120 may be mounted in the housing 144. Also, the coolant inlet 135, through which a coolant may enter the anode 110 and the cathode 120, and the coolant outlet 137, through which a coolant having circulated in the anode 110 and the cathode 120 exits, may be formed in the housing 144. The coolant inlet 135 and the coolant outlet 137 may be provided on each of the anode 110 and the cathode 120.

The transmissive member 142 may be configured to block the reactive gas contained in the transmissive member 142 from external air, and to allow heat generated in the arc discharge apparatus 100 to be transmitted as radiant energy through the transmissive member 142. The transmissive member 142 may include a material having a high transmissivity, e.g., glass or quartz.

A spectrum of the radiant energy emitted from the arc discharge apparatus 100 may be determined by the reactive gas contained in the body unit 140. In this case, the reactive gas used in a process may be determined according to a process condition, and may be, e.g., argon (Ar) gas, xenon (Xe) gas, or krypton (Kr) gas.

The electrode unit may be mounted on the housing 144, and may include the anode 110 and the cathode 120 disposed to face each other. The anode 110 and the cathode 120 may be disposed in the body unit 140 so that one end of the anode 110 faces one end of the cathode 120.

The anode 110 and the cathode 120 may receive power necessary for an arch discharge from the outside. When voltage is applied to the anode 110 and the cathode 120, an arc for generating plasma is formed between the cathode 120 and the anode 110. Electrons emitted from the cathode 120 collide with the reactive gas contained in the body unit 140, thereby generating plasma.

The cathode 120 may be provided so that a first end of the cathode 120 is fixed to the housing 144 and a second end of the cathode 120 that is opposite to the first end of the cathode 120 faces the anode 110. The cathode 120 may include a cathode main body 120m fixed to the housing 144 and a cathode tip 120t coupled to the cathode main body 120m, i.e., the cathode tip 120t may include the second end of the cathode 120 facing the anode 110.

The cathode 120 may be formed of a metal having a high melting point, e.g., tungsten or a tungsten alloy, in order to operate even in a high-temperature condition. Also, the cathode 120 may further include a metal having a high thermal conductivity, e.g., copper or brass, in order to improve heat dissipation efficiency. Also, the cathode 120 may further include a metal having excellent mechanical properties, e.g., brass or stainless steel, in order to increase a mechanical strength.

The cathode 120 may include the cathode tip 120t disposed on a front end of the cathode 120 to face the anode 110. The front end of the cathode 120, i.e., the cathode tip 120t, is directly exposed to an arc, and may be exposed to heat at a temperature of about 3000° C. or more in a process under high temperature and high pressure. Since the cathode tip 120t is formed of metal having a high melting point, it may prevent the cathode 120 from being damaged due to a high-temperature arc and a high-temperature plasma.

In detail, the cathode tip 120t may include a metal having a high melting point of about 3000 K or more, so that the cathode 120 may be used in a high-temperature condition. For example, the cathode tip 120t may include tungsten having a melting point of about 3695 K, or may include a tungsten alloy obtained by adding, e.g., hafnium, thorium, yttrium, or a combination thereof, to tungsten. The cathode 120 may emit electrons through the cathode tip 120t, and an end of the cathode tip 120t facing the anode 110 may have a sharp point to easily emit the electrons.

A first end of the anode 110 may be fixed to the housing 144, and an anode tip 110t for preventing damage to the anode 110 may be provided at a second end of the anode 110 that is opposite to the first end of the anode 110. The anode 110 may include a main body portion 110m fixed to the housing 144 and the anode tip 110t coupled to the main body portion 110m and facing the cathode 120.

The anode 110 may be formed of a metal having a high melting point, e.g., tungsten or a tungsten alloy, in order to operate in a high-temperature condition. Also, the anode 110 may further include a metal having a high thermal conductivity, e.g., copper or brass, in order to improve heat dissipation efficiency. Also, the anode 110 may further include a metal having excellent mechanical properties, e.g., brass or stainless steel, in order to increase mechanical strength.

The anode tip 110t provided on a front end of the anode 110 may prevent the anode 110 from being damaged due to a high-temperature arc and a high-temperature plasma. That is, the front end of the anode 110, i.e., the anode tip 110t, that is directly exposed to an arc may be exposed to heat at a temperature of about 3000° C. or more in a process under a high temperature and a high pressure. As the anode tip 110t includes metal having a high melting point in order to be used in a high-temperature condition, it may prevent the remainder of the anode 110 from being damaged due to a high-temperature arc and a high-temperature plasma.

For example, the anode tip 110t may include tungsten having a melting point of 3695 K, or may include a tungsten alloy obtained by adding, e.g., hafnium, thorium, yttrium, or a combination thereof, to tungsten. A surface of the anode tip 100t that faces the cathode 120 may have a planar, e.g., flat, shape.

Referring to FIG. 2 along with FIG. 1, the anode 110 may include the main body portion 110m fixed to the housing 144 and the anode tip 110t coupled to the main body portion 110m. The main body portion 110m and the anode tip 110t may be formed of different materials.

For example, the main body portion 110m may include parts formed of brass, copper, or a combination thereof. A part of the main body portion 110m that is coupled to the housing 144 may include brass or stainless steel that is a metal having excellent mechanical properties. Also, a part of the main body portion 110m that contacts a cooling line 130 (see FIG. 3) may include a metal having a high thermal conductivity.

The anode tip 110t may include tungsten or a tungsten alloy. The anode tip 110t may be formed of tungsten or a tungsten alloy that is a metal having a high melting point in order to prevent the anode 110, e.g., the front end of the anode 110, from being damaged due to a high-temperature arc and a high-temperature plasma.

The main body portion 110m and the anode tip 110t may be coupled to each other by using an adhesive member 160 disposed on an adhesive surface between the main body portion 110m and the anode tip 110t. For example, the adhesive member 160 may be used by disposing a metal, e.g., silver or copper, between the main body portion 110m and the anode tip 110t, and then coupling the main body portion 110m and the anode tip 110t by using welding to heat and melt the metal.

However, a method of coupling the main body portion 110m and the anode tip 110t is not limited to the above method using the adhesive member 160. For example, the main body portion 110m and the anode tip 110t may be coupled to each other by using a mechanical coupling device. In this case, in order to prevent the mechanical coupling device from being damaged due to high temperature heat generated during a plasma discharge, the mechanical coupling device may be formed of a material having high corrosion resistance and high heat resistance.

Referring to FIG. 3 along with FIG. 1, the cooling line 130 is provided in the anode 110 as a passage through which a coolant circulates to cool the anode 110, e.g., the cooling line 130 may circulate through the main body portion 110m and the anode tip 110t. A first side of the cooling line 130 may be connected to the coolant inlet 135 of the anode 110, and a second side of the cooling line 130 may be connected to the coolant outlet 137 of the anode, e.g., the first and second sides of the cooling line 130 may be inlet and outlet ends of the cooling line 130 that are located at a same side of the anode 110.

A coolant may enter the cooling line 130 through the coolant inlet 135 of the anode, may flow through the cooling line 130 within the anode 110, and may exit the cooling line 130 through the coolant outlet 137 of the anode 110. As the coolant flows through the cooling line 130, the coolant may remove heat from the anode 110, thereby cooling the anode 110.

The coolant that cools the anode 110 while circulating in the cooling line 130 may be a gaseous coolant or a liquid coolant. For example, process cooling water (PCW) may be used as the coolant.

The cooling line 130 may include a first fluid passage 131 and a second fluid passage 133. In detail, the first fluid passage 131 may extend from the coolant inlet 135 toward a portion adjacent to the anode tip 110t, e.g., the first fluid passage 131 may have a pipe shape extending along a center line of the anode 110 through the main body portion 110m and through a portion of the anode tip 110t. The second fluid passage 133 may extend from an outlet portion 131 out of the first fluid passage 131 along an inner wall 115 of the anode 110 to the coolant outlet 137. For example, the second fluid passage 133 may have an approximate hollow cylinder shape that extends along the inner wall 115 of the anode 110, e.g., the hollow cylinder shape of the second fluid passage may have an annular cross-section that is concentric with the first fluid passage 131 (FIG. 4), so the coolant flows from the outlet portion 131 out of the first fluid passage 131 in the anode tip 110t along the entire inner wall 115 back to the coolant outlet 137. For example, as illustrated in FIGS. 3-4, an interior of the anode 110 may be processed to form the first and second fluid passage 131 and 133 as concentric tubular shapes, with the second fluid passage 133 at least partially defining the inner wall 115 of the anode 110.

In this case, the first fluid passage 131 and the second fluid passage 133 may be formed not to overlap, i.e., to be unidirectional so as not to interfere with, each other. Also, at least a part of the second fluid passage 133 may be formed to surround an outer circumferential surface of the first fluid passage 131.

In detail, a coolant that flows through the cooling line 130 may flow through the first fluid passage 131 into a portion of the anode tip 110t, so the coolant is adjacent to an inner upper wall 115a of the anode 110. That is, as illustrated in FIG. 3, coolant at the outlet portion 131 out of the first fluid passage 131 faces the, e.g., center of the, inner upper wall 115a, so the coolant flowing from first fluid passage 131 into the second fluid passage 133 directly contacts the inner upper wall 115a. Then, the coolant may flow through the second fluid passage 133 while contacting the inner upper wall 115a of the anode 110 and inner side walls 115b of the anode 110. A coolant circulating in the cooling line 130 may cool the anode 110 while contacting the anode 110, thereby preventing the anode 110 from being damaged. e.g., from being melted at a high temperature.

A central portion of the inner upper wall 115a of the anode 110 may have a planar shape, e.g., parallel to the surface of the anode tip 100t that faces the cathode 120. A temperature of a central portion of the front end of the anode 110 that is most frequently exposed to an arc may be the highest in the anode 110. That is, a temperature distribution at the inner upper wall 115a of the anode 110 may include the highest temperature at the central portion of the upper wall 115a that is the closest to the central portion of the front end of the anode 110, while the temperature gradually decreases as a distance from the central portion of the upper wall 115a increases. Accordingly, the central portion of the inner upper wall 115a of the anode 110 may have a planar shape, as shown in FIG. 3, so the a temperature gradient in the longitudinal direction of the anode 110 may be reduced.

In contrast, for example, if a metal guide were to be added to the central portion of an inner upper wall of an anode in order to facilitate coolant flow in a smooth streamline direction, the metal guide could lead to an increased temperature gradient from the central portion of the upper wall in a longitudinal direction of the anode. As such, cooling efficiency would have been reduced.

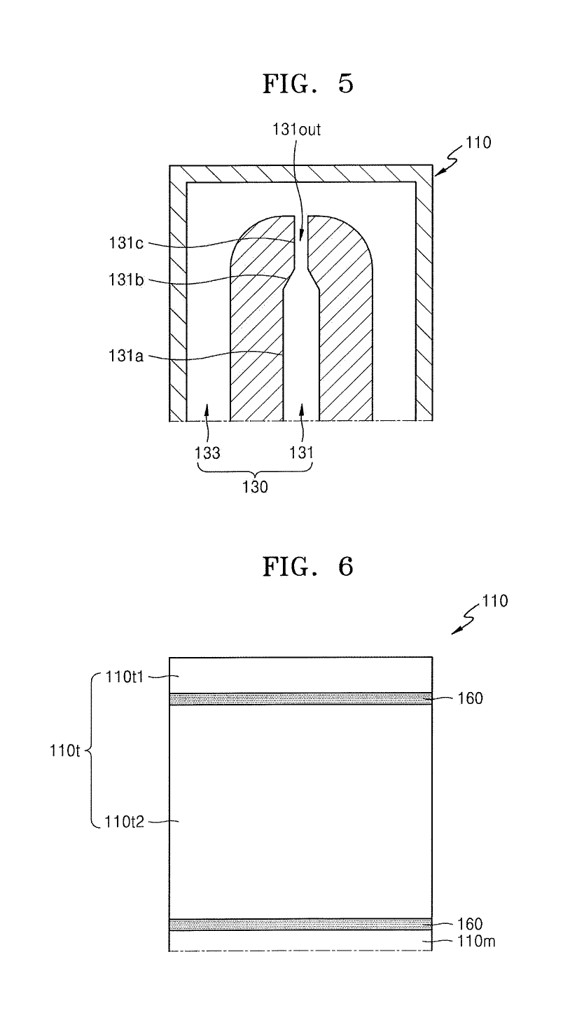

For example, the first fluid passage 131 of the cooling line 130 may include a nozzle region in order to increase a flow velocity of a coolant discharged from the outlet portion 131 out of the first fluid passage 131. This will be described in more detail below with reference to FIG. 5.

Referring to FIG. 4, centres C of the first fluid passage 131 and the second fluid passage 133 may be the same. That is, on a plane perpendicular to the longitudinal direction of the anode 110 at a portion adjacent to the front end of the anode 110, an inner wall of the anode 110 may be spaced apart by the same interval from an outer circumferential surface of the first fluid passage 131. On the perpendicular plane, a flow rate of a coolant flowing through the second fluid passage 133 may be maintained constant without increasing at a specific portion, and thus heat exchange between the anode 110 and the coolant may occur uniformly.

While FIG. 4 illustrates round annular cross-sections, the cross-section of the anode 110 taken along the plane perpendicular to the longitudinal direction of the anode 110 may have a circular, a quadrangular shape, or any other convenient shape. Further, a cross-section of the cooling line 130 formed in the anode 110 may have a circular shape. However, the present exemplary embodiment is not limited thereto, and the cross-section of the cooling line 130 may have a quadrangular shape or any other convenient shape.

A void may be potentially formed in a process of forming the adhesive member 160 by heating silver or copper. Therefore, referring back to FIG. 3, in order to prevent cooling efficiency from being reduced due to a void in an adhesive portion between the main body portion 110m and the anode tip 110t of the anode 110, the adhesive member 160 may be configured not to be disposed between the front end of the anode 110 and the inner upper wall 115a of the anode 110 that contacts the cooling line 130. That is, according to example embodiments, a distance between the adhesive member 160 and the inner upper wall 115a may be increased.

If the adhesive member 160 were to be disposed between the front end of the anode 110 and the inner upper wall 115a of the anode 110, a void having a predetermined volume or more could have obstructed heat transfer between the anode tip 110t and the cooling line 130. As a result, heat dissipation efficiency could have been reduced, the life of the anode 110 could have been reduced due to the reduced heat dissipation efficiency, and moreover, the adhesive member 160 could have been heated to a temperature equal to or higher than a melting point to be melted.

Accordingly, the adhesive member 160 according to example embodiments is disposed at a level lower than that of the inner upper wall 115a of the anode 110, thereby preventing a void that may be formed in the adhesive member 160 from reducing cooling efficiency. For example, in some exemplary embodiments, a distance ‘t’ between the front end of the anode 110 and an adhesive surface between the main body portion 110m and the anode tip 110t may be greater than a diameter D of the anode tip 110t. In other words, a distance between the front end of the anode 110 and the adhesive member 160 may be greater than the diameter D of the anode tip 110t. The diameter D of the anode tip 110t may refer to a diameter at the front end of the anode 110.

In general, as thermal load applied to the anode 110 that is used for an arc discharge increases, the diameter D of the anode tip 110t provided on the front end of the anode 110 may increase. Accordingly, as thermal load necessary for a process increases, the adhesive member 160 may be disposed farther away from the front end of the anode 110. That is, since the distance′t′ between the front end of the anode 110 and the adhesive surface between the main body portion 110m and the anode tip 110t is greater than the diameter D of the anode tip 110t, the adhesive member 160 may be prevented from being melted at a temperature equal to or higher than a melting point.

A distance between the front end of the anode 110 and the adhesive member 160 for preventing the adhesive member 160 from being melted may be determined according to a condition such as thermal load, a flow rate of a coolant, and/or a size of the anode 110. The distance ‘t’ between the front end of the anode 110 and the adhesive surface between the main body portion 110m and the anode tip 110t may be determined to be less than the diameter D according to other conditions.

Although FIGS. 2 through 4 illustrate a structure of the anode 110 and the cooling line 130 formed in the anode 110, the cathode 120 may have substantially the same structure as that of the anode 110 of FIGS. 2 through 4 and substantially the same cooling line as the cooling line 130 formed in the anode 110 may be formed in the cathode 120.

FIG. 5 is a cross-sectional view illustrating a part of the anode 110 according to an exemplary embodiment.

Referring to FIGS. 1 and 5, the cooling line 130 in which a coolant circulates may be formed in the anode 110, and may include the first fluid passage 131 and the second fluid passage 133. The first end of the first fluid passage 131 may be connected to the coolant inlet 135, and the second end that is opposite to the first end of the first fluid passage 131 may extend to a portion adjacent to the front end of the anode 110.

An eddy current may be generated due to an insufficient momentum of a coolant at a portion where the flow of the coolant sharply changes, e.g., a portion between an inner wall of the anode 110 and the outlet portion 131 out of the first fluid passage 131. The eddy current may obstruct heat transfer between the coolant and the anode 110, thereby reducing cooling efficiency.

Also, while the anode 110 is cooled by using a coolant, cooling efficiency may be affected by a flow rate or a flow velocity of the coolant. However, a method of increasing a flow rate of a coolant may have a limitation due to a volume of the anode 110, and a method of increasing a flow velocity of a coolant by increasing a capacity of a pump may increase process costs.

Accordingly, in some exemplary embodiments, in order to improve cooling efficiency by increasing a flow velocity of a coolant without increasing a capacity of a pump, the first fluid passage 131 may include a nozzle region for increasing a flow velocity at a portion adjacent to the outlet portion 131 out of the first fluid passage 131.

The first fluid passage 131 including the nozzle region may include a first pipe 131a, a second pipe 131b, and a third pipe 131c. The first pipe 131a may extend from the coolant inlet 135, through which a coolant of the first fluid passage 131 enter. The third pipe 131c may be spaced apart from the first pipe 131a, and may extend toward the outlet portion 131 out of the first fluid passage 131. The third pipe 131c may have a cross-sectional area that is less than that of the first pipe 131a. The second pipe 131b may be disposed between the first pipe 131a and the third pipe 131c, and may have a cross-sectional area that decreases toward the third pipe 131c. In this case, a cross-sectional area of the outlet portion 131 out of the first fluid passage 131 may be less than a cross-sectional area of the coolant inlet 135 in the first fluid passage 131.

Cross-sectional areas of the first pipe 131a, the second pipe 132b, the third pipe 131c, and the outlet portion 131 out of the first fluid passage 131 refer to areas of cross-sections taken in a direction perpendicular to a direction in which the first pipe 131a, the second pipe 131b, the third pipe 131c, and the outlet portion 131 out of the first fluid passage 131 extend.

While a coolant continuously circulates, since a cross-sectional area of the second pipe 131b decreases toward the third pipe 131c, a flow velocity of the coolant flowing through the second pipe 131b increases toward the third pipe 131c. As described above, the first fluid passage 131 may be configured to include the nozzle region with a reduced cross-sectional area at a portion adjacent to the outlet portion 131 out of the first fluid passage 131. As a result, a flow velocity of a coolant at the outlet portion 131 out of the first fluid passage 131 may be higher than a flow velocity of a coolant at the coolant inlet 135.

Also, even when a streamline of coolant is sharply changed when a coolant discharged from the outlet portion 131 out of the first fluid passage 131 meets an inner wall of the anode 110, the coolant with the increased flow has sufficient momentum, thereby preventing an eddy current from being generated. Also, since a flow velocity of a coolant may be increased without increasing a capacity of a pump, process costs may be reduced.

Although the cooling line 130 is formed in the anode 110 in FIG. 5, a cooling line formed in the cathode 120 may have substantially the same structure as that of the cooling line described with reference to FIG. 5.

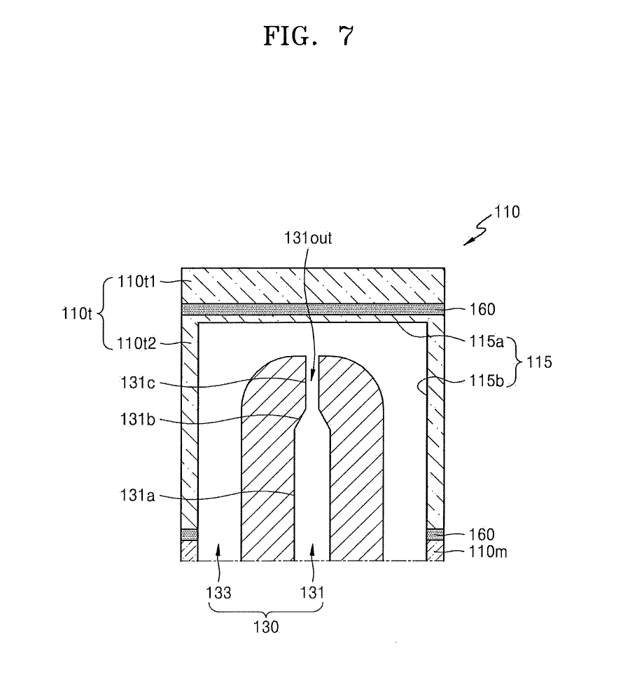

FIG. 6 is a side view illustrating a part of the anode 110 according to an exemplary embodiment. FIG. 7 is a cross-sectional view illustrating a part of the anode 110.

Referring to FIGS. 6 and 7 along with FIG. 1, the anode 110 may include the main body portion 110m connected to the housing 144, and the anode tip 110t coupled to the main body portion 110m. In this case, the anode tip 110t may include a first tip 110t1 disposed on the front end of the anode 110, and a second tip 110t2 disposed between the first tip 110t1 and the main body portion 110m.

The main body portion 110m may include parts formed of brass, copper, or a combination thereof. The main body portion 110m and the anode tip 110t may be coupled to each other by using the adhesive member 160 disposed between the main body portion 110m and the anode tip 110t.

For example, the first tip 110t1 and the second tip 110t2 may include different materials. In another example, the first tip 110t1 and the second tip 110t2 may be integrally formed with each other by using a same material. In some exemplary embodiments, the first tip 110t1 may be disposed on the front end of the anode 110 and may be formed of a metal having a high melting point, e.g., tungsten or a tungsten alloy, in order to prevent damage to the anode 110 due to a high temperature. The second tip 110t2 may be disposed between the first tip 110t1 and the main body portion 110m, and may directly contact the cooling line 130. The second tip 110t2 may be formed of a metal having a high thermal conductivity to improve heat dissipation efficiency of the cooling line 130. For example, the second tip 110t2 may be formed of copper having a high thermal conductivity.

In this case, the first tip 110t1 and the second tip 110t2 may be coupled to each other by using the adhesive member 160 disposed on an adhesive surface between the first tip 110t1 and the second tip 110t2. In this case, the adhesive member 160 may be formed by heating or melting a metal, e.g., silver, copper, or a combination thereof, by using welding.

Also, the cooling line 130 may include the first fluid passage 131 extending from the coolant inlet 135 to a portion adjacent to the second tip 110t2, and the second fluid passage 133 extending from the outlet portion 131 out of the first fluid passage 131 to the coolant outlet 137. In this case, the first fluid passage 131 may include a nozzle region at the outlet portion 131out of the first fluid passage 131, and thus a flow velocity of a coolant at the outlet portion 131 out of the first fluid passage 131 may be higher than a flow velocity of a coolant at the coolant inlet 135.

For example, the cooling line 130 may include the first pipe 131a extending from a portion through which a coolant of the first fluid passage 131 enters, the third pipe 131c spaced apart from the first pipe 131a, extending toward the outlet portion 131 out of the first fluid passage 131, and having a cross-sectional area that is less than that of the first pipe 131a, and the second pipe 131b disposed between the first pipe 131a and the third pipe 131c and having a cross-sectional area that decreases toward the third pipe 131c.

That is, since a flow velocity of a coolant at a portion that contacts the inner wall 115 of the anode tip 110t is increased, an eddy current may be prevented from being generated and cooling efficiency may be improved. Due to the improved cooling efficiency, the adhesive member 160 disposed between the front end of the anode 110 and the inner upper wall 115a of the anode 110 may be prevented from being heated to a temperature equal to or higher than a melting point.

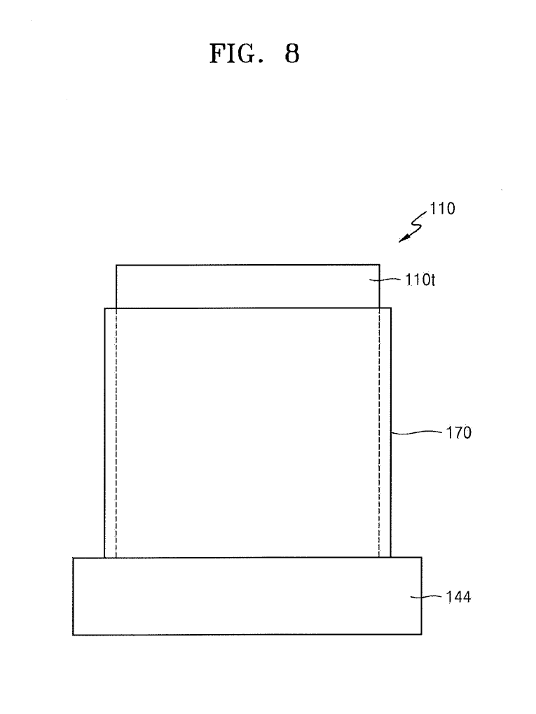

FIG. 8 is a side view of the anode 110 according to an exemplary embodiment.

Referring to FIG. 8 along with FIG. 1, the anode 110 may include the main body portion 110m mounted on the housing 144, the anode tip 110t coupled to the main body portion 110m, and a coating unit 170 formed to surround an outer circumferential surface of the anode 110.

The anode tip 110t may include, e.g., tungsten or a tungsten alloy, that is a metal having a high melting point in order to prevent the anode 110 from being damaged due to a high-temperature arc or a high-temperature plasma. The main body portion 110m may be formed of, e.g., copper, brass, or stainless steel, in order to compensate for a low thermal conductivity and a low electrical conductivity of tungsten. That is, the anode tip 110t that is directly exposed to an arc may include tungsten or a tungsten alloy in order to endure a high temperature, and a part of the main body portion 110m that needs a high thermal conductivity may be formed of copper and a part of the main body portion 110m that needs a high mechanical strength may be formed of brass.

The coating unit 170 may be further formed to surround the outer circumferential surface of the anode 110, thereby preventing brass or copper from being corroded and contaminating the inside of the arc discharge apparatus 100. For example, portions formed of a metal such as brass or copper may be corroded when contacting a coolant or being disposed at a high temperature, so particles of the corroded metal may contaminate the inside of the arc discharge apparatus 100, e.g., transmission characteristics for emitting radiant energy to the outside of the arc discharge apparatus 100 may be reduced due to the corroded brass or copper attached to the transmissive member 142. Therefore, the coating unit 170 according to example embodiments is provided to prevent or substantially minimize corrosion.

The coating unit 170 may be formed to surround the entire outer circumferential surface of the anode 110, or may be formed to surround a portion other than a portion (e.g., the anode tip 110t formed of tungsten or a tungsten alloy) formed of tungsten or the like having high corrosion resistance and high heat resistance. The coating unit 170 may be formed of a material having high corrosion resistance, e.g., tungsten, a tungsten alloy, or stainless steel, in order to prevent the main body portion 110m from being corroded.

Although the coating unit 170 is provided on the anode 110 in FIG. 8, the cathode 170 may include substantially the same coating unit as the coating unit 170 described with reference to FIG. 8.

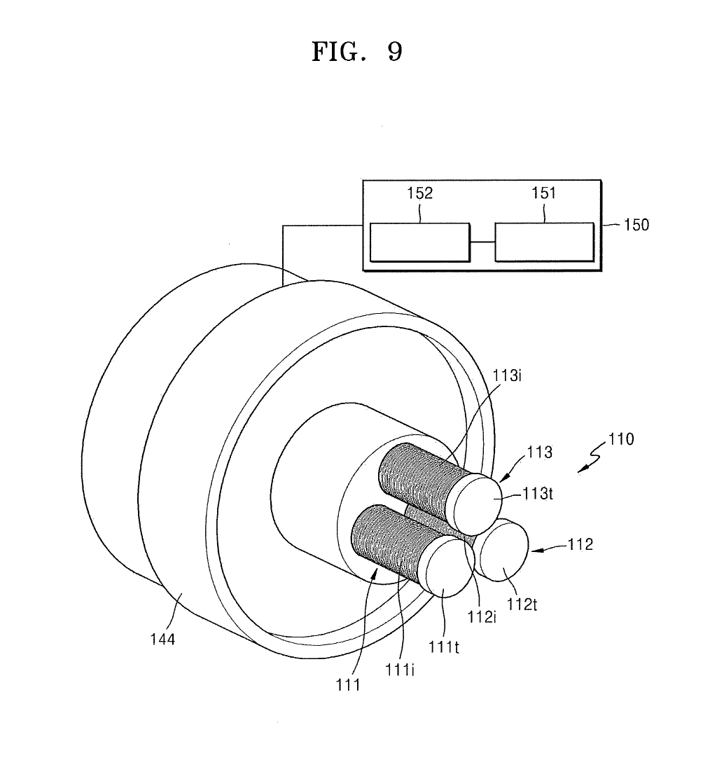

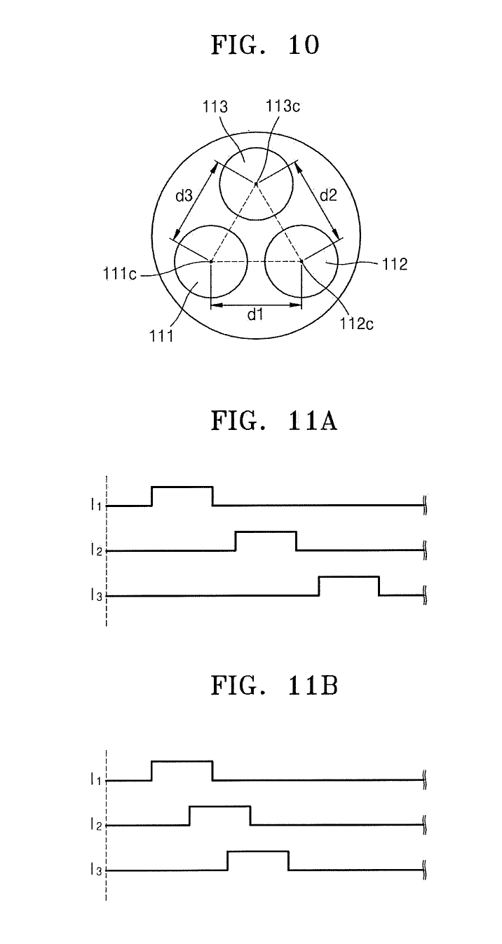

FIG. 9 is a perspective view of the anode 110 according to an exemplary embodiment. FIG. 10 is a plan view seen from the front end of the anode 110 of FIG. 9. FIGS. 11A and 11B are diagrams illustrating current supplied to an induction coil provided in the anode 110.

Referring to FIGS. 9 and 10, a plurality of the anodes 110 may be formed. For example, a first anode 111, a second anode 112, and a third anode 113 may be formed. The first through third anodes 111, 112, and 113 may respectively include anode tips 111t, 112t, and 113t formed on front ends of the first through third anodes 111, 112, and 113. Also, a cooling line may be formed in each of the first through third anodes 111, 112, and 113 as described above.

When one anode 110 is used, a temperature may excessively increase at a specific portion of the front end of the anode 110. However, since the first through third anodes 111, 112, and 113 may distribute thermal load, the life of each of the first through third anodes 111, 112, and 113 may be extended.

The first through third anodes 111, 112, and 113 may be provided to have the same shape and the same size. Accordingly, thermal load distributed to the first through third anodes 111, 112, and 113 may be maintained more constant.

Also, the first through third anodes 111, 112, and 113 may be radially spaced apart from one another at same intervals. For example, a distance d1 between a center 111c of the first anode 111 and a center 112c of the second anode 112, a distance d2 between the center 112c of the second anode 112 and a center 113c of the third anode 113, and a distance 3d between the center 113c of the third anode 113 and the center 111c of the first anode 111 may be the same.

Induction coils 111i, 112i, and 113i configured to generate an induced magnetic field may be respectively wound around outer circumferential surfaces of the first through third anodes 111, 112, and 113. Also, a power control unit 150 may supply power to the induction coils 111i, 112i, and 113i according to a preset condition. The power control unit 150 may be connected to the induction coils 111i, 112i, and 113i respectively provided on the first through third anodes 111, 112, and 113, and may be configured to control power supplied to the induction coils 111i, 112i, and 113i.

The power control unit 150 may include a power supply source 151 and a power controller 152. The power supply source 151 may supply power to the induction coils 111i, 112i, and 113i, and the power controller 152 may selectively supply current to the induction coils 111i, 112i, and 113i according to the preset condition.

When current is supplied to the induction coils 111i, 112i, and 113i respectively wound around side surfaces of the first through third anodes 111, 112, and 113, an induced magnetic field for inducing an arc and a plasma may be generated for each electrode. Accordingly, an arc formed between the cathode 120 and the first through third anodes 111, 112, and 113 may be controlled by controlling current flowing in the induction coils 111i, 112i, and 113i by using the power control unit 150.

Referring to FIGS. 11A and 11B along with FIG. 9, the power control unit 150 may be configured to uniformly distribute power to the induction coils 111i, 112i, and 113i. The power control unit 150 may distribute power by assigning times for which power is supplied to the induction coils 111i, 112i, and 113i.

In this case, as current flows in the induction coils 111i, 112i, and 113i for the assigned times, an induced magnetic field for inducing an arc and a plasma may be generated at the first through third anodes 111, 112, and 113 for the assigned times.

For example, as shown in FIG. 11A, current I1 may be supplied to the induction coil 111i of the first anode 111 and may be cut off, then current I2 may be supplied to the induction coil 112i of the second anode 112 and may be cut off, and then current I3 may be supplied to the induction coil 113i of the third anode 113. That is, times for which current is supplied to the induction coils may not overlap one another and lengths of the times for which current is supplied to the induction coils 111i, 112i, and 113i may be the same.

Also, as shown in FIG. 11B, the current I2 may be supplied to the induction coil 112i of the second anode 112 before the current I1 supplied to the induction coil 111i of the first anode 111 is cut off, and the current I3 may be supplied to the induction coil 113i of the third anode 113 before the current I2 supplied to the induction coil 112i of the second anode 112 is cut off. Times for which current is supplied to the induction coils 111i, 112i, and 113i may partially overlap one another and lengths of the times for which current is supplied to the induction coils 111i, 112i, and 113i may be the same.

Since power supplied to the first through third anodes 111, 112, and 113 is distributed, thermal load may be prevented from increasing on a specific portion. As a result, a temperature on a specific portion of each of the front ends of the first through third anodes 111, 112, and 113 may not be excessively increased and temperature uniformity at the front ends of the first through third anodes 111, 112, and 113 may be improved. That is, a temperature difference between a central portion and an edge portion of the anode 110 may be reduced.

Due to the improvement in temperature uniformity at the front ends of the first through third anodes 111, 112, and 113, a problem that heat dissipation efficiency is reduced at an edge of the front end of the anode 110 whose temperature is relatively low when only one anode 110 is provided may be solved. Due to the improvement in temperature uniformity, overall cooling efficiency may be improved, thereby extending the life of the anode 110.

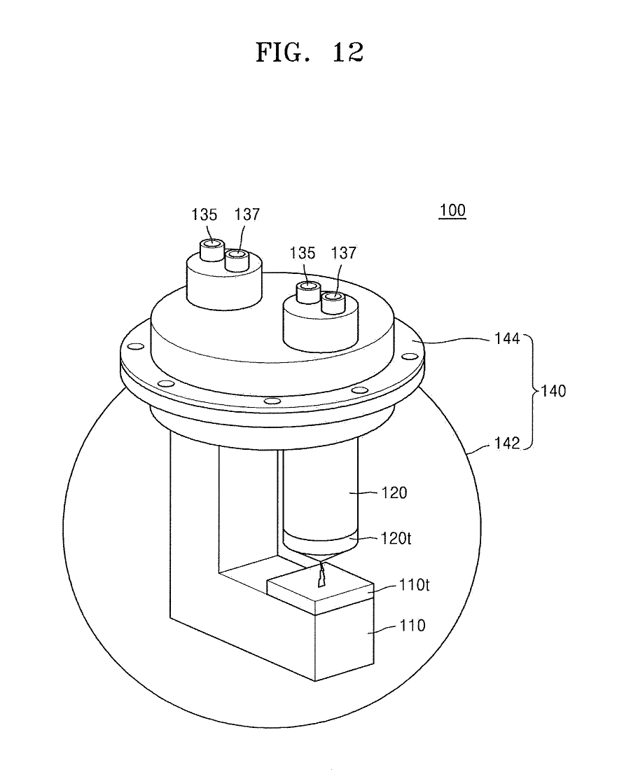

FIG. 12 is a perspective view of the arc discharge apparatus 100 according to an exemplary embodiment.

Referring to FIG. 12, the arc discharge apparatus 100 may include the body unit 140, the anode 110, and the cathode 120. The anode 110 and the cathode 120 may be substantially the same as those described with reference to FIGS. 1 through 11B.

The body unit 140 may include the transmissive member 142 and the housing 144, and may have a bulb shape. Unlike in FIG. 1, the housing 144 may not be separated and may be integrally provided. The anode 110 and the cathode 120 may be mounted on the housing 144. The coolant inlet 135 and the coolant outlet 137 may be formed on the anode 110 and on the cathode 120 in the housing 144. Also, the transmissive member 142 may be mounted on the housing 144 to surround the anode 110 and the cathode 120.

The body unit 140 may have a pipe shape as shown in FIG. 1, instead of the bulb shape. Alternatively, the body unit 140 may be provided to have any of various other shapes according to a method of mounting the body unit 140 in a chamber in which a plasma process is performed.

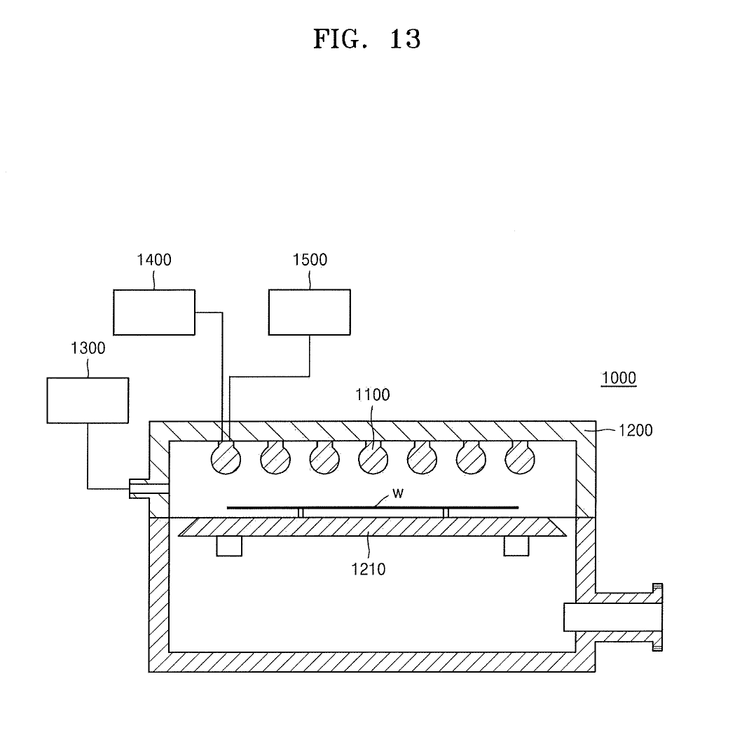

FIG. 13 is a cross-sectional view of a plasma processing system 1000 according to an exemplary embodiment.

Referring to FIG. 13, the plasma processing system 1000 may include a chamber 1200, a gas supply unit 1300 configured to supply a process gas into the chamber 1200, a substrate support 1210 on which a substrate W is mounted, an arc discharge apparatus 1100 mounted on one surface of the chamber 1200 and configured to receive power and generate an arc discharge, and a power supply unit 1500 configured to supply power to an electrode provided in the arc discharge apparatus 1100.

The chamber 1200 may provide a space in which a plasma process may be performed. The chamber 1200 may include an upper chamber and a lower chamber. While a plasma process is performed, the upper chamber and the lower chamber may contact each other to close off an inner space from the outside. While the substrate W is loaded and unloaded, the upper chamber and the lower chamber may be separated from each other so that the substrate W is transferred into and out of the chamber 1200.

Also, an exhaust duct for discharging a gas or a by-product in the chamber 1200 may be formed in the chamber 1200. Although not shown in FIG. 13 in detail, the exhaust duct may be connected to a vacuum pump, and a pressure control valve and a flow rate control valve may be further provided.

The substrate support 1210 may be mounted in the space provided in the chamber 1200, and the substrate W may be mounted on one surface of the substrate support 1210. The substrate support 1210 may include support fins. The support fins may support edge portions of a rear surface of the substrate W so that the substrate W is spaced apart by a predetermined distance from the one surface of the substrate support 120.

The gas supply unit 1300 may supply a process gas through an inlet duct provided in one side of the chamber 1200. The process gas such as an inert gas may be supplied into the chamber 1200 to form a process atmosphere in the chamber 1200. The gas supply unit 1300 may include a control valve for adjusting a supplied process gas.

However, a configuration of the gas supply unit 1300 may not be limited thereto, and the gas supply unit 1300 may be configured to uniformly spray a process gas to the entire chamber 1200 through a shower head provided on an upper side of the chamber 1200.

The arc discharge apparatus 1100 may be provided on one surface of the chamber 1200. The arc discharge apparatus 1100 may receive power necessary for an arc discharge from the power supply unit 1500. When the power supply unit 1500 supplies power to an electrode provided in the arc discharge apparatus 1100 to form an arc, a reactive gas in the arc discharge apparatus 1100 may be discharged to generate a plasma.

The arc discharge apparatus 1100 may be configured to apply heat at a time and a temperature meeting a process condition to the substrate W mounted on the substrate support 1210. One or more arc discharge apparatuses 1100 may be provided.

The arc discharge apparatus 1100 may correspond to the arc discharge apparatus described with reference to FIGS. 1 through 12.

The plasma processing system 1000 of the present exemplary embodiment may prevent damage to the electrode provided in the arc discharge apparatus 1100, and thus may extend the life of the electrode. Accordingly, process costs that may be incurred when the life of the electrode provided in the arc discharge apparatus 1100 ends and thus the electrode is frequently replaced may be reduced. Also, heat meeting a preset condition may be applied to the substrate W, and thus the reliability of a plasma process may be improved.

Also, the plasma processing system 100 may be used in, for example, an annealing process, and in particular, in a rapid thermal process. However, the present exemplary embodiment is not limited thereto, and the plasma processing system 1000 may be used in any of various other processes such as surface treatment, atomic layer deposition, or etching.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. An arc discharge apparatus, comprising:
a body unit including a housing and a transmissive member fixed to the housing, the housing having a coolant inlet and a coolant outlet; and
an electrode unit on the housing, the electrode unit including an anode and a cathode facing each other,
wherein the anode includes:
a main body portion connected to the housing,
an anode tip coupled to the main body portion, and
a cooling line in the anode and in contact with an inner wall of the anode tip, the cooling line being connected to the coolant inlet and to the coolant outlet.

2. The arc discharge apparatus as claimed in claim 1, wherein the main body portion and the anode tip include different materials.

3. The arc discharge apparatus as claimed in claim 1, wherein the main body portion includes brass, copper, or a combination thereof.

4. The arc discharge apparatus as claimed in claim 1, wherein the main body portion and the anode tip are coupled to each other via an adhesive member, an interface between the adhesive member and the anode tip defining an adhesive surface.

5. The arc discharge apparatus as claimed in claim 4, wherein a distance between the adhesive surface and a front surface of the anode is greater than a diameter of the anode tip.

6. The arc discharge apparatus as claimed in claim 1, wherein the cooling line includes a first fluid passage extending from the coolant inlet to a portion adjacent to the anode tip, and a second fluid passage extending from an outlet portion of the first fluid passage to the coolant outlet.

7. The arc discharge apparatus as claimed in claim 6, wherein at least a part of the second fluid passage surrounds an outer circumferential surface of the first fluid passage.

8. The arc discharge apparatus as claimed in claim 6, wherein the first fluid passage includes:
a first pipe extending from the coolant inlet;
a third pipe spaced apart from the first pipe and extending toward the outlet portion of the first fluid passage, the third pipe having a cross-sectional area that is less than a cross-sectional area of the first pipe; and
a second pipe between the first pipe and the third pipe and having a cross-sectional area that decreases toward the third pipe.

9. (canceled)

10. The arc discharge apparatus as claimed in claim 1, wherein:
the anode tip includes a first tip on a front end of the anode and a second tip between the first tip and the main body portion,
the cooling line includes a first fluid passage extending from the coolant inlet to a portion adjacent to the second tip, and a second fluid passage extending from an outlet portion of the first fluid passage to the coolant outlet, and
a flow velocity of a coolant at the outlet portion of the first fluid passage is higher than a flow velocity of a coolant at the coolant inlet.

11. The arc discharge apparatus as claimed in claim 10, wherein the first tip and the second tip includes different materials.

12. The arc discharge apparatus as claimed in claim 11, wherein the first tip includes tungsten and the second tip includes copper.

13. The arc discharge apparatus as claimed in claim 10, wherein the first tip and the second tip are coupled to each other by an adhesive member.

14. The arc discharge apparatus as claimed in claim 1, wherein the anode includes a plurality of anodes.

15. The arc discharge apparatus as claimed in claim 14, wherein:
each of the plurality of anodes includes an induction coil wound around an outer circumferential surface thereof to generate an induced magnetic field, and
the arc discharge apparatus further comprises a power control unit to selectively supply power to the induction coil of each of the plurality of anodes.

16.-17. (canceled)

18. The arc discharge apparatus as claimed in claim 1, wherein the anode further comprises a coating surrounding an outer circumferential surface thereof.

19. (canceled)

20. An arc discharge apparatus, comprising:
a body unit including a housing and a transmissive member fixed to the housing, the housing having a coolant inlet and a coolant outlet; and
an electrode unit on the housing, the electrode unit including an anode and a cathode facing each other,
wherein the anode includes:
a main body portion connected to the housing,
an anode tip coupled to the main body portion, the anode tip including a first tip on a front end of the anode, and a second tip between the first tip and the main body portion, and the first tip including tungsten or a tungsten alloy, and
a cooling line in the anode and in contact with an inner wall of the anode tip, the cooling line being connected to the coolant inlet and to the coolant outlet.

21. The arc discharge apparatus as claimed in claim 20, wherein the first tip and the second tip include a same material and are integral with each other.

22. The arc discharge apparatus as claimed in claim 21, wherein the main body portion and the second tip are coupled to each other via an adhesive member, an interface between the adhesive member and the second tip defining an adhesive surface, and a distance between the adhesive surface and the front end of the anode is greater than a diameter of the anode tip.

23. The arc discharge apparatus as claimed in claim 20, wherein:
the second tip includes copper, the first tip and the second tip being coupled to each other via an adhesive member,
the cooling line includes a first fluid passage extending from the coolant inlet to a portion adjacent to the second tip, and a second fluid passage extending from an outlet portion of the first fluid passage to the coolant outlet, and
a flow velocity of a coolant at the outlet portion of the first fluid passage is higher than a flow velocity of a coolant at the coolant inlet.

24. (canceled)

25. A plasma processing system, comprising:
a chamber to provide a space for a plasma process;
a gas supply unit to supply a process gas into the chamber;
a substrate support in the chamber, a substrate being mounted on the substrate support; and
an arc discharge apparatus on one surface of the chamber to receive power and generate an arc discharge, the arc discharge apparatus including:
a body unit including a housing and a transmissive member fixed to the housing, the housing having a coolant inlet and a coolant outlet, and
an electrode unit on the housing, the electrode unit including an anode and a cathode facing each other,
wherein the anode includes:
a main body portion connected to the housing,
an anode tip coupled to the main body portion, and
a cooling line in the anode and in contact with an inner wall of the anode tip, the cooling line being connected to the coolant inlet and to the coolant outlet.

26.-34. (canceled)
